(19) United States
(12) Patent Application Publication
(10) Pub. No.: US 2025/0027202 A1
(43) Pub. Date: Jan. 23, 2025

(54) METHODS OF ADJUSTING UNIFORMITY, AND RELATED APPARATUS AND SYSTEMS, FOR SEMICONDUCTOR MANUFACTURING

(71) Applicant: Applied Materials, Inc., Santa Clara, CA (US)

(72) Inventors: Tetsuya ISHIKAWA, San Jose, CA (US); Kim Ramkumar VELLORE, San Jose, CA (US)

(21) Appl. No.: 18/225,007

(22) Filed: Jul. 21, 2023

(51) Int. Cl. C23C 16/46; G05D 23/27

(52) U.S. Cl. CPC C23C 16/46; G05D 23/27

(57) ABSTRACT

The present disclosure relates to methods of adjusting uniformity for substrate processing, and related apparatus and systems, for semiconductor manufacturing. In one or more embodiments, a heating power applied to a set of one or more heat sources is adjusted by an adjustment factor. In one or more embodiments, a method of adjusting uniformity. The method includes scanning a sensor across one or more sections to take a plurality of readings, generating a signal profile including the plurality of readings, and analyzing the signal profile by comparing the signal profile to a range. The method includes adjusting one or more heating parameters if at least one portion of the signal profile is outside of the range. The adjusting includes identifying a set of one or more heat sources that correlate with the at least one portion of the signal profile, and adjusting a heating power by an adjustment factor.

### BACKGROUND

### Field

The present disclosure relates to methods of adjusting uniformity for substrate processing, and related apparatus and systems, for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate. For example, temperature non-uniformities and/or physical non-uniformities can affect deposition uniformity. As an example, the temperature of the substrate and/or temperature(s) of processing chamber component(s) can affect deposition uniformity. As another example, stress and/or warpage of the substrate can cause temperature non-uniformities and/or deposition non-uniformities.

It can be difficult to account for non-uniformities, and non-uniformities can result in processing delays, substrate waste, and reduced throughput.

Therefore, a need exists for improved method, apparatus, and systems for adjusting uniformity.

### SUMMARY

The present disclosure relates to methods of adjusting uniformity for substrate processing, and related apparatus and systems, for semiconductor manufacturing. In one or more embodiments, a heating power applied to a set of one or more heat sources is adjusted by an adjustment factor.

In one or more embodiments, a method of adjusting uniformity for substrate processing applicable for semiconductor manufacturing includes heating an internal volume of a processing chamber using a target value. The method includes scanning a sensor across one or more sections to take a plurality of readings. The method includes generating a signal profile including the plurality of readings, and analyzing the signal profile by comparing the signal profile to a range. The method includes adjusting one or more heating parameters if at least one portion of the signal profile is outside of the range. The adjusting includes identifying a set of one or more heat sources that correlate with the at least one portion of the signal profile, and adjusting a heating power by an adjustment factor for the set of one or more heat sources.

In one or more embodiments, a non-transitory computer readable medium applicable for semiconductor manufacturing includes instructions that when executed cause a plurality of operations to be conducted. The plurality of operations include analyzing a signal profile by comparing the signal profile to a range. The range is less than a threshold ratio of a target value. The threshold ratio is 0.10. The analyzing includes identifying a signal difference in the signal profile, and determining if the signal difference is within or outside of the range. The plurality of operations include adjusting one or more heating parameters if at least one portion of the signal profile is outside of the range. The adjusting includes identifying a set of one or more heat sources that correlate with the at least one portion of the signal profile, and adjusting a heating power by an adjustment factor for the set of one or more heat sources.

In one or more embodiments, a system for processing substrates and applicable for semiconductor manufacturing includes a chamber body that includes one or more sidewalls, and a window. The one or more sidewalls and the window at least partially define an internal volume. The system includes one or more heat sources configured to heat the internal volume, a substrate support disposed in the internal volume, and a sensor configured to sense parameters in the internal volume. The system includes a controller including instructions that, when executed, cause a plurality of operations to be conducted. The plurality of operations include generating a signal profile, the signal profile including a plurality of readings. The plurality of operations include analyzing the signal profile by comparing the signal profile to a range. The range is less than a threshold ratio of a target value. The threshold ratio is 0.10. The analyzing includes identifying a signal difference in the signal profile, and determining if the signal difference is within or outside of the range. The plurality of operations include adjusting one or more heating parameters if at least one portion of the signal profile is outside of the range. The adjusting includes identifying a set of one or more heat sources that correlate with the at least one portion of the signal profile, and adjusting a heating power by an adjustment factor for the set of one or more heat sources.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic side view of a uniformity profile 200 across the substrate and/or the substrate support shown in FIG. 1, according to one or more embodiments.

FIG. 3 is a schematic block diagram view of a method of adjusting uniformity for substrate processing applicable for semiconductor manufacturing, according to one or more embodiments.

FIG. 4 is a schematic flow diagram view of an exemplary implementation of the method shown in FIG. 3, according to one or more embodiments.

FIG. 5 is a schematic top view of the upper heat sources shown in FIG. 1, according to one or more embodiments.

FIG. 6 is a schematic side view of the upper heat sources shown in FIG. 5, according to one or more embodiments.

FIG. 7 is a schematic top view of the processing chamber during operations of the method shown in FIG. 3, according to one or more embodiments.

FIG. 8 is a schematic graphical view of an exemplary signal profile created using the implementation shown in FIG. 7, according to one or more embodiments.

FIG. 9 is a schematic top view of the processing chamber during operations of the method shown in FIG. 3, according to one or more embodiments.

FIG. 10 is a schematic graphical view of an exemplary signal profile created using the implementation shown in FIG. 9, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to methods of adjusting uniformity for substrate processing, and related apparatus and systems, for semiconductor manufacturing. In one or more embodiments, a heating power applied to a set of one or more heat sources is adjusted by an adjustment factor.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

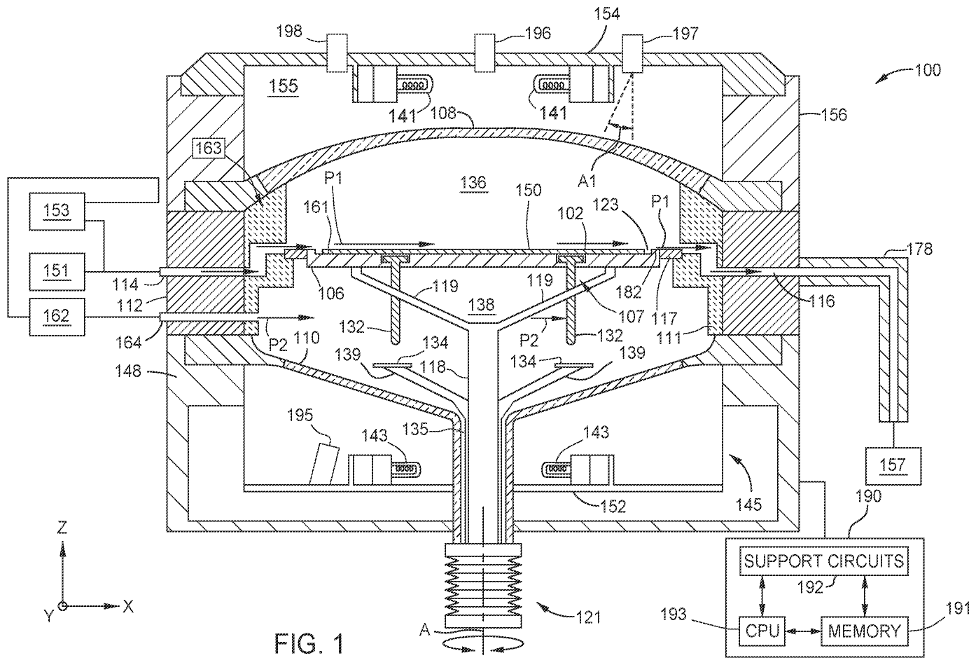

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper window 108 and the lower window 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper window and a lid 154. The plurality of upper heat sources 141 form a portion of the upper heat source module 155.

The plurality of lower heat sources 143 are disposed between the lower window 110 and a floor 152. The plurality of lower heat sources 143 form a portion of a lower heat source module 145. The upper window 108 is an upper dome and/or is formed of an energy transmissive material, such as quartz. The lower window 110 is a lower dome and/or is formed of an energy transmissive material, such as quartz.

An upper volume 136 and a purge volume 138 are formed between the upper window 108 and the lower window 110. The upper volume 136 and the purge volume 138 are part of an internal volume defined at least partially by the upper window 108, the lower window 110, and one or more liners 111, 163. In one or more embodiments, the upper volume 136 is a processing volume.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the upper volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the upper volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (Cl). In one or more embodiments, the one or more process gases P1 include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the upper volume 136. The one or more gas inlets 114 are in fluid communication with one or more flow gaps between the upper liner 163 and a lower liner 111. The one or more second gas inlets 175 are in fluid communication with the one or more inlet openings 183 of the upper liner 163.

During a deposition operation (e.g., an epitaxial growth operation), the one or more process gases P1 flow through the one or more gas inlets 114, through the one or more gaps, and into the upper volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the upper volume 136.

The processing system includes one or more sensors 195, 196, 197, 198 (e.g., temperature sensors) configured to measure parameter(s) (e.g., temperature(s)) within the processing chamber 100. In one or more embodiments, the one or more sensors 195, 196, 197, 198 include a central sensor 196 and one or more outer sensors 195, 197, 198. A controller 190 (described below) can control the one or more sensors 195, 196, 197, 198 and one or more heat sources 141, 143, and can conduct method(s) adjusting uniformity of substrate processing using at least one of the one or more sensors 195, 196, 197, 198 and one or more heat sources 141, 143. In one or more embodiments, the one or more sensors 195, 196, 197, 198 each include a pyrometer, such as a pyrometer that includes a silicon sensor. In one or more embodiments, each sensor 195, 196, 197, 198 is an optical sensor, such as an optical pyrometer. The present disclosure contemplates that sensors other than pyrometers may be used, and/or one or more of the sensors 195, 196, 197, 198 can measure properties other than temperature.

In one or more embodiments, the one or more sensors 195, 196, 197, 198 include one or more upper sensors 196, 197, 198 disposed above the substrate 102 and adjacent the lid 154, and one or more lower sensors 195 disposed below the substrate 102 and adjacent the floor 152. The present disclosure contemplates that at least one of the one or more lower sensors 195 can be vertically aligned below at least one of the upper sensors 196, 196, 197 (such as outer sensor 197).

Each sensor 195, 196, 197, 198, can be a single-wavelength sensor device or a multi-wavelength (such as dual-wavelength) sensor device. In one or more embodiments, the system including the process chamber 100 includes any one, any two, or any three of the four illustrated sensors 195, 196, 197, 198. In one or more embodiments, the process chamber 100 includes one or more additional sensors, in addition to the sensors 195, 196, 197, 198. In one or more embodiments, the process chamber 100 may include sensors disposed at different locations and/or with different orientations than the illustrated sensors 195, 196, 197, 198.

As shown, a controller 190 is in communication with the processing chamber 100 and is used to control processes and methods, such as the operations of the methods described herein.

The controller 190 is configured to receive data or input as sensor readings from sensor(s) (such as one or more of the sensors 195, 196, 197, 198). The sensors can include, for example: sensors that monitor growth of layer(s) on the substrate 102; and/or sensors that monitor temperatures of the substrate 102, the substrate support 106, and/or the liners 111, 163. The controller 190 is equipped with or in communication with a system model of the processing chamber 100. The system model includes a heating model, a temperature uniformity model, a film uniformity model, a film deposition rate model, a coating model, a rotational position model, and/or a gas flow model. The system model is a program configured to estimate parameters (such as a signal profile (e.g., a temperature profile) of the substrate 102 and/or the substrate support 106, a gas flow rate, a gas pressure, a rotational position of component(s), a heating profile, a coating condition, and/or a cleaning condition) within the processing chamber 100 throughout a deposition operation and/or a cleaning operation. The controller 190 is further configured to store readings and calculations. The readings and calculations include previous sensor readings, such as any previous sensor readings within the processing chamber 100. The readings and calculations further include the stored calculated values from after the sensor readings are measured by the controller 190 and run through the system model. Therefore, the controller 190 is configured to both retrieve stored readings and calculations as well as save readings and calculations for future use. Maintaining previous readings and calculations enables the controller 190 to adjust the system model over time to reflect a more accurate version of the processing chamber 100.

The controller 190 can monitor heating, generate a signal profile (e.g., a temperature profile), identify set(s) of one or more heat sources, adjust a heating profile, adjusting heating power(s), estimate an optimized parameter, adjust the one or more sensors, generate an alert on a display, halt a deposition operation, initiate a chamber downtime period, delay a subsequent iteration of the deposition operation, initiate a cleaning operation, halt the cleaning operation, and/or otherwise adjust the process recipe.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

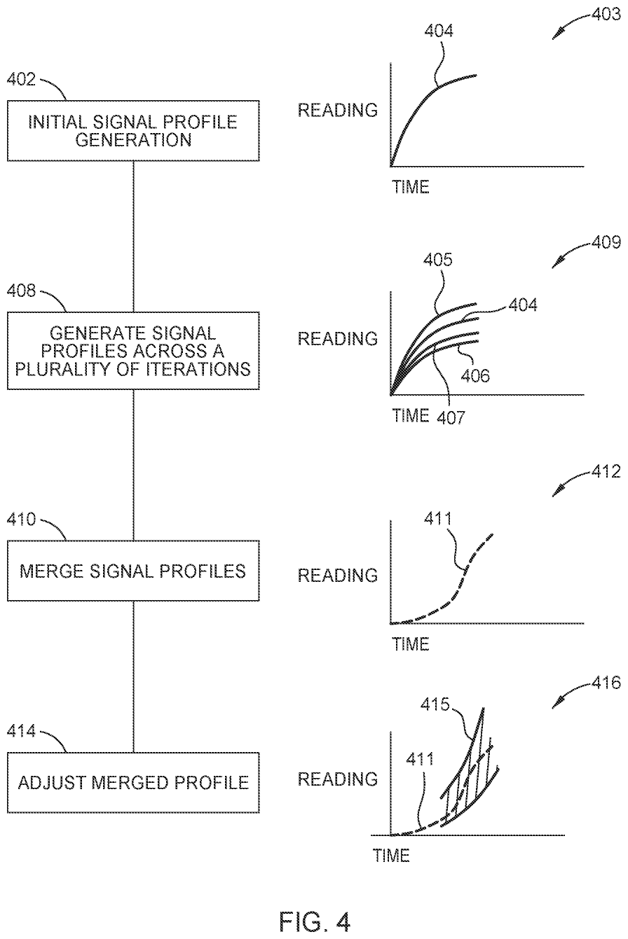

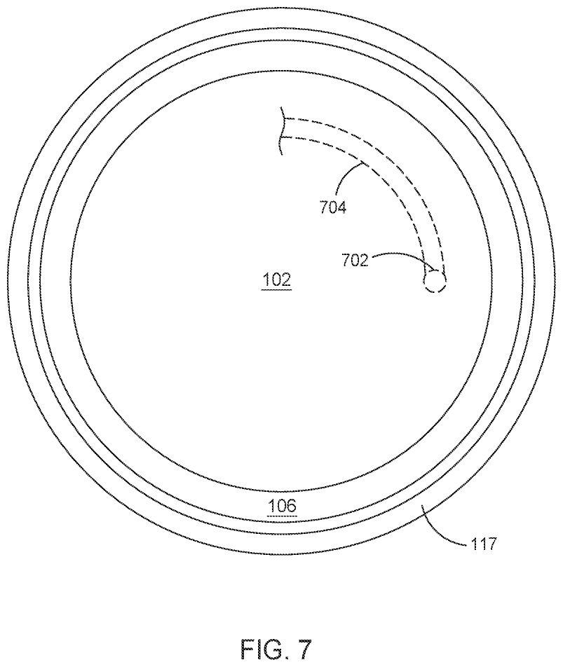

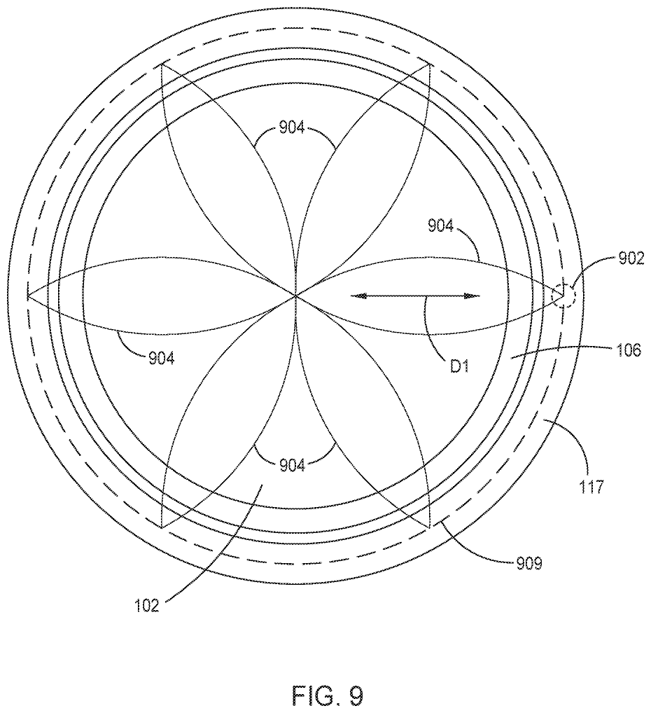

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., target value(s), reading(s), signal difference(s), signal profile(s), heating power(s) (e.g., applied to one or more of the heat sources 141, 143), adjustment factor(s), threshold ratio(s), range(s) and/or training range(s) with which the signal difference(s) are compared, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of operations of: method 300, FIG. 4, FIG. 7, and/or FIG. 9 to be conducted in relation to the processing chamber 100. The controller 190 and the processing chamber 100 are at least part of a system for processing substrates.

The various operations described herein (such as the operations of method 300, FIG. 4, FIG. 7, and/or FIG. 9) can be conducted automatically using the controller 190, or can be conducted automatically or manually with certain operations conducted by a user.

In one or more embodiments, the controller 190 includes a mass storage device, an input control unit, and a display unit. The controller 190 can monitor the temperature of the substrate 102, the temperature of the substrate support 106, the process gas flow, and/or the purge gas flow. In one or more embodiments, the controller 190 includes multiple controllers 190, such that the stored readings and calculations and the system model are stored within a separate controller from the controller 190 which controls the operations of the processing chamber 100. In one or more embodiments, all of the system model and the stored readings and calculations are saved within the controller 190.

The controller 190 is configured to control the deposition, the cleaning, the rotational position, the heating, and gas flow through the processing chamber 100 by providing an output to the controls for the sensors 195, 196, 197, 198, the upper heat sources 141, the lower heat sources 143, the process gas source 151, the purge gas source 162, the motion assembly 121, and/or the exhaust pump 157.

The controller 190 is configured to adjust the output to the controls based on the sensor readings, the system model, and the stored readings and calculations. The controller 190 includes embedded software and a compensation algorithm to calibrate measurements. The controller 190 can include one or more machine learning algorithms and/or artificial intelligence algorithms that estimate optimized parameters for the uniformity analysis operations, the deposition operations, and/or the cleaning operations.

The one or more machine learning algorithms and/or artificial intelligence algorithms may implement, adjust and/or refine one or more algorithms, inputs, outputs or variables described above. Additionally or alternatively, the one or more machine learning algorithms and/or artificial intelligence algorithms may rank or prioritize certain aspects of adjustments of the process chamber 100 and/or method(s) (such as the method 300) relative to other aspects of the process chamber 100 and/or method(s) (such as the method 300). The one or more machine learning algorithms and/or artificial intelligence algorithms may account for other changes within the processing systems such as hardware replacement and/or degradation. In one or more embodiments, the one or more machine learning algorithms and/or artificial intelligence algorithms account for upstream or downstream changes that may occur in the processing system due to variable changes of the process chamber 100 and/or method(s) (such as the method 300). For example, if variable “A” is adjusted to cause a change in aspect “B” of the process, and such an adjustment unintentionally causes a change in aspect “C” of the process, then the one or more machine learning algorithms and/or artificial intelligence algorithms may take such a change of aspect “C” into account. In such an embodiment, the one or more machine learning algorithms and/or artificial intelligence algorithms embody predictive aspects related to implementing the process chamber 100 and/or the method(s) (such as the method 300. The predictive aspects can be utilized to preemptively mitigate unintended changes within a processing system.

The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize, for example, optimized parameters such as target value(s), reading(s), signal difference(s), signal profile(s), heating power(s) (e.g., applied to one or more of the heat sources 141, 143), adjustment factor(s), threshold ratio(s), range(s) and/or training range(s) with which the signal difference(s) are compared, a cleaning recipe, and/or a processing recipe.

In one or more embodiments, the controller 190 automatically conducts the operations described herein without the use of one or more machine learning algorithms and/or artificial intelligence algorithms. In one or more embodiments, the controller 190 compares measurements (such as readings and/or signal differences) to data in a look-up table and/or a library to identify a set of one or more heat sources and/or adjust a heating power for the set of one or more heat sources. The controller 190 can stored measurements as data in the look-up table and/or the library.

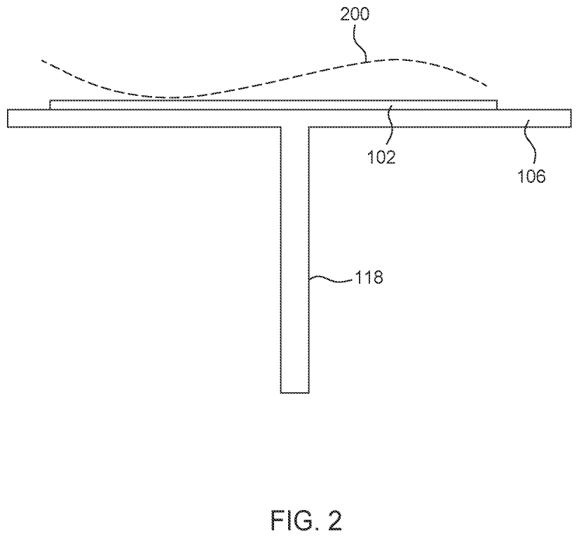

FIG. 2 is a schematic side view of a uniformity profile 200 across the substrate 102 and/or the substrate support 106 shown in FIG. 1, according to one or more embodiments. As shown the uniformity profile 200 can include one or more process non-uniformities across a direction that is parallel to the diameter of the substrate 102 and/or the diameter of the substrate support 106.

The process non-uniformit(ies) can indicate, for example, a non-uniformity of the substrate (such as the substrate 102), and/or the substrate support (such as the substrate support 106). The process non-uniformity can be a non-uniformity in temperature or material (such as component thickness of the substrate and/or the substrate support, coating thickness (e.g., of silicon carbide coated on graphite or reacted material from process gases) of the substrate support, machining defects of the substrate support, and/or surface roughness of the substrate support). The non-uniformity can be caused by insufficient and/or non-uniform cleaning. The process non-uniformity can be a non-uniformity in substrate shape caused by warpage (e.g., bowing). Warpage can be caused, for example, by non-uniform heating and/or properties of the substrate. The present disclosure contemplates that the process non-uniformity can indicate other non-uniformities. The non-uniformity can be caused, for example, by component placement (such as non-uniformities in the distances between the lift pins 132 and the substrate 102 and/or misalignment of the substrate 102 relative to a center of the substrate support 106). The non-uniformity can be caused, for example, by component erosion (such as erosion of the substrate support 106, such as erosion of a coating on the substrate support 106), and/or component reaction (such as reaction of process gases with the substrate support 106). The non-uniformity can be caused, for example, by process drift (such as heat source drift).

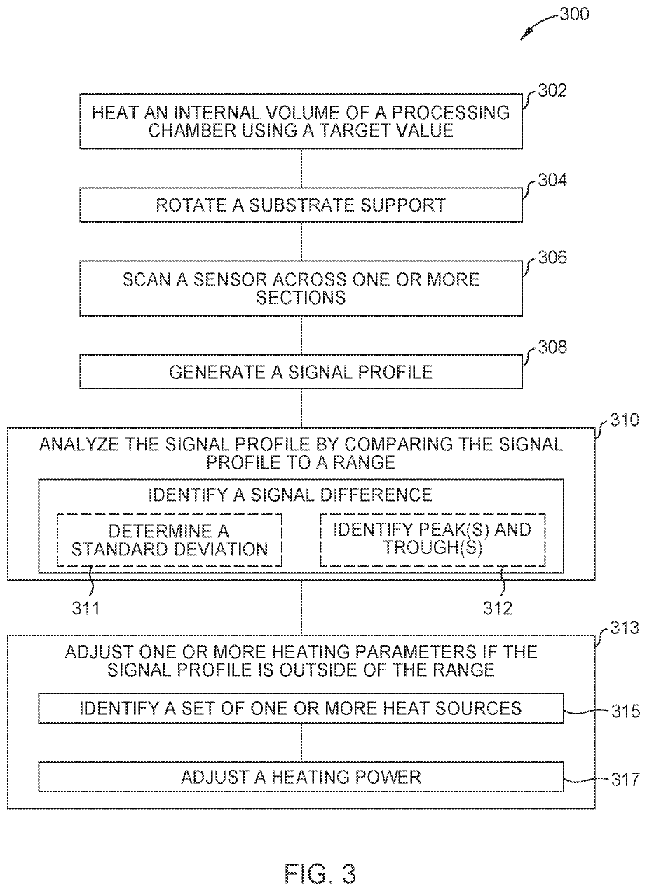

FIG. 3 is a schematic block diagram view of a method 300 of adjusting uniformity for substrate processing applicable for semiconductor manufacturing, according to one or more embodiments.

Operation 302 of the method 300 includes heating an internal volume of a processing chamber using a target value. The target value can be pre-set, for example, by a user and/or by the controller 190. In one or more embodiments, the target value described herein is a target temperature. In one or more embodiments, the target temperature is within a range of 400 degrees Celsius to 550 degrees Celsius. In one or more embodiments, the target temperature is within a range of 700 degrees Celsius to 800 degrees Celsius.

Operation 304 includes rotating a substrate support.

Operation 306 includes scanning a sensor across one or more sections to take a plurality of readings. In one or more embodiments, the sensor is a temperature sensor and the plurality of readings are a plurality of temperature readings. In one or more embodiments, the one or more sections are disposed along the substrate support or along a substrate positioned on the substrate support. The one or more sections extend azimuthally and are disposed at one or more radial locations. In one or more embodiments, the plurality of readings are taken at a sampling frequency while the substrate support is rotated at a rotation speed. The rotation speed is a ratio of the sampling frequency. In one or more embodiments, the ratio is less than 0.1. In one or more embodiments, the ratio of the rotation speed is 0.015 or less. In one or more embodiments, the ratio of the rotation speed is 0.010 or less, such as within a range of 0.0025 to 0.0075. The sampling frequency is within a range of 1 Hz to 10 KHz. In one or more embodiments, the sampling frequency is within a range of 90 Hz to 110 Hz, such as about 100 Hz. In one or more embodiments, the rotation speed is within a range of 0.50 cycles (e.g., rotations) per second to 0.55 cycles per second, such as about 32 cycles per minute. The readings are taken at a reading rate of at least 100 data points per revolution of the rotation of the substrate support. In one or more embodiments, the reading rate is at least 200 data points per revolution, for example at least 400 data points per revolution, such as 600 or more data points per revolution. Other values are contemplated for the rotation speed, the sampling frequency, the ratio, and/or the reading rate.

The scanning of operation 306 can be conducted while rotating the substrate support.

Operation 308 includes generating a signal profile including the plurality of readings. In one or more embodiments, the signal profile is a temperature profile.

Operation 310 includes analyzing the signal profile by comparing the signal profile to a range. The analyzing includes identifying a signal difference in the signal profile, and determining if the signal difference is within or outside of the range. In one or more embodiments, the signal difference is a temperature difference.

The identifying of the signal difference includes (at optional operation 311) determining a standard deviation of the signal profile, and the signal difference is the standard deviation.

The identifying of the signal difference includes (at optional operation 312) identifying one or more peaks and one or more troughs of the signal profile. In one or more embodiments, the signal difference is a difference between one of the one or more peaks and an adjacent trough of the one or more troughs. The adjacent trough can be within one revolution of the one of the one or more peaks. In one or more embodiments, the signal difference is a difference between a highest peak of the one or more peaks and a lowest trough of the one or more troughs.

Operation 313 includes adjusting one or more heating parameters if at least one portion of the signal profile is outside of the range.

Operation 313 includes (at operation 315) identifying a set of one or more heat sources that correlate with the at least one portion of the signal profile.

In one or more embodiments, the set of one or more heat sources are part of a plurality of heat sources that are powered during the heating of operation 302. In one or more embodiments, the set of one or more heat sources are in addition to the plurality of heat sources that are powered during the heating of operation 302. In one or more embodiments, the set of one or more heat sources is correlated with at least one of the one or more troughs of the signal profile. In one or more embodiments, the set of one or more heat sources is correlated with at least one of the one or more peaks of the signal profile.

Operation 313 includes (at operation 317) adjusting a heating power by an adjustment factor for the set of one or more heat sources. The heating power, prior to adjustment, can be a zero value or a non-zero value. In one or more embodiments, the adjustment factor is a ratio equal to a threshold ratio of the target value added to a value of 1.0. The heating power can be increased (e.g., multiplied) or decreased (e.g., divided) by the adjustment factor. The threshold ratio can be pre-set, such as user selected and/or determined by the controller 190. In one or more embodiments, the threshold ratio is within a range of 0.005 to 0.10, such as within a range of 0.005 to 0.01.

The adjustment factor can be pre-set (such as user selected and/or determined by the controller 190) without the use of the threshold ratio. In one or more embodiments, the adjustment factor is within a range of 1.005 to 1.10, such as within a range of 1.005 to 1.01.

In one or more embodiments, a field of view of the sensor is moved during the scanning of operation 306 such that the one or more sections extend radially, and the range is less than the threshold ratio. The threshold ratio is 0.10. In one or more embodiments, the threshold ratio is 0.081, such as 0.051.

In one or more embodiments, the field of view of the sensor is substantially stationary during the scanning of operation 306 such that the one or more sections extend arcuately (e.g., azimuthally, such as circumferentially), and the range is less than the threshold ratio. The threshold ratio is 0.025. In one or more embodiments, the threshold ratio is 0.01, such as 0.0081 or 0.0051.

The correlation of operation 315 includes determining the set of one or more heat sources that were heating (e.g., directed to—such as vertically aligned above or below) a region encompassing the field of view at the time(s) that the at least one portion of the signal profile is outside of the range. The determining can be based on the rotational position of the substrate support 106, which can be based on time(s) (within the signal profile) that the at least one portion of the signal profile is outside of the range. In one or more embodiments, the correlation of operation 315 includes determining the set of one or more heat sources that were heating (e.g., directed to—such as vertically aligned above or below) a region encompassing the field of view at the time(s) corresponding to the one or more troughs of the signal profile.

In one or more embodiments, the correlation of operation 315 includes determining the set of one or more heat sources that were heating (e.g., directed to—such as vertically aligned above or below) a region encompassing the field of view at the time(s) (within the signal) of the one or more troughs and/or the one or more peaks.

The present disclosure contemplates that the heating power can be adjusted for the set of one or more heat sources in a manner that is pulsed or non-pulsed. For example, the adjustment factor can be applied to the heating power in a manner that is pulsed such that the heating power oscillates between a first power value (which does not include the adjustment factor) and a second power value (which includes the adjustment factor). The first power value can be a zero or non-zero number. In one or more embodiments, the heating power is adjusted using a pulse frequency that is about equal to the rotation speed of the substrate support.

One or more operations of the method 300 can be conducted automatically and/or one or more operations of the method 300 can be conducted manually. For example, operations 302-310 and operation 313 can be conducted automatically. As another example, operations 302-310 can be conducted automatically, and the method 300 can generate an alert to a user for the user to conduct operation 313 manually. The method 300 can include, for example, initiation of chamber downtime, replacement of the substrate support, adjustment of process recipe (such as the target value, e.g., the target temperature) and/or heating power, and/or flagging the substrate for re-processing (such as re-deposition).

The information of the method 300 (such as the target value(s), the reading(s), the signal difference(s), the signal profile(s), the heating power(s), the adjustment factor(s), the threshold ratio(s), and/or the range(s)) can be stored and tracked as data. In one or more embodiments, the data is analyzed and/or compared using averages, derivatives, modeling, imaging, and/or with other data analysis techniques. As an example, one or more optical sensors can capture images, and the intensity of the images can be analyzed for detection of the readings (e.g., the temperature readings).

The present disclosure contemplates that first signal profile(s) of the substrate support can be generated (e.g., using a lower sensor) and second signal profile(s) of the substrate can be generated (e.g., using an upper sensor). The first signal profile(s) and the second signal profile(s) can be compared to each other. For example, when a substrate is placed on a substrate support, a first signal profile (e.g., first temperature profile) is generated for the substrate support and a second signal profile (e.g., second temperature profile) is generated for the substrate. An increase (e.g., temperature increase) in the first signal profile of the substrate support and a decrease (e.g., a temperature decrease) in the second signal profile of the substrate, when occurring of area(s) corresponding to the substrate, can indicate that the substrate is warped (e.g., bowed) when placed on the substrate support, and the areas(s) are the area(s) where the substrate is spaced from the substrate support. Similarly, a decrease (e.g., a temperature decrease) in the first signal profile of the substrate support and an increase (e.g., a temperature increase) in the second signal profile of the substrate, when occurring of area(s) corresponding to the substrate, can indicate that the substrate is warped (e.g., bowed) when placed on the substrate support, and the areas(s) are the area(s) where the substrate contacts the substrate support. Using the methods described herein, set(s) of one or more heat sources (such as set(s) of the upper heat sources 141) are correlated with the area(s) where the substrate is spaced from the substrate support, and the heating power is adjusted for the correlated set(s) to reduce the warping (e.g., bowing).

The present disclosure contemplates that a training model for training the system and/or the methods described herein can involve film thickness readings and associated film thickness profiles that are generated. The film thickness readings can be taken during processing and/or after processing. The film thickness profile(s) can be analyzed in place of the temperature profile(s) described above, or the film thickness profile(s) can be merged with the temperature profile(s) described above such that data at the same locations along the substrate(s) are merged (e.g., averaged). The present disclosure contemplates that the training model for training the system and/or the methods described herein can be at least partially unsupervised. For example, the training model can account for film thickness profile(s) that are measured on substrate(s) after the substrate(s) are processed.

The present disclosure contemplates that the readings described herein can be analyzed—without units—before the readings are correlated to measurements having certain units. For example, the readings taken at operation 306 can be unit-less values and/or can be used to generate the signal profile (at operation 308) and analyze the signal profile (at operation 310) before the readings are correlated (using an emissivity of the substrate and/or the substrate support) to temperature measurements having units in, for example, Celsius or Fahrenheit. For example, the readings can be a measured intensity.

The present disclosure contemplates that methods described herein (such as the method 300) can be conducted during a deposition operation and/or before and/or after a deposition operation. For example, the method 300 can conducted during a simulation process without the substrate 102 present in the chamber 100.

FIG. 4 is a schematic flow diagram view of an exemplary implementation of the method 300 shown in FIG. 3, according to one or more embodiments.

Operation 402 includes an initial signal profile (e.g., an initial temperature profile) generation using one or more sensors (e.g., temperature sensors), and graph 403 shows part of a signal profile 404 (e.g., temperature profile) of readings (e.g., temperature readings) versus time using data collected during the initial signal profile generation. The time can be the time it takes for the one or more sensors to scan across the one or more sections. Conduction of operation 402 can include, for example, conducting operations 302, 304, 306, and 308 of the method 300.

Operation 408 includes generating by conducting operations 306 and 308 of the method 300 one or more additional times to generate additional signal profiles 405-407 (e.g., temperature profiles) across a plurality of iterations shown in graph 409. Parts of the signal profiles 405-407 are shown in the graph 409. For example, a more complete showing of the signal profiles 405-407 can include sinusoidal patterns. The iterations can be, for example, a plurality of heating powers, a plurality of adjustment factors, a plurality of target values (e.g., target temperatures), a plurality of radial locations for the one or more sections, a plurality of deposition operations (which can be conducted across a plurality of substrates), a plurality of substrate supports (with which a plurality of deposition operations can be conducted), and/or a plurality of components (such as the substrate 102 and the substrate support 106) for the one or more sections.

Each signal profile 404-407 corresponds to one of the plurality of iterations. If the iterations are target temperatures or heating powers, the target temperatures can be achieved by a plurality of different bias power levels applied to the heat sources 141, 143. The signal profiles 404-407 and/or the associated readings (e.g., temperature readings) can be stored (e.g., in a library in the memory). The signal profiles 404-407 can be generated at different times (such as on different days) and can include process drift (such as sensor, heater drift, and/or substrate drift (for example from erosion).

Operation 410 includes merging the signal profiles 404-407 (which can be stored in the library in the memory) to create a merged profile 411 shown in graph 412 (part of the merged profile 411 is shown in the graph 412). The merged profile 411 can be analyzed at operation 310 and can be used to determine if one or more heating parameters are to be adjusted. The merging can include averaging values along the signal profiles 404-407 (which can be line-fitted), and the averaging can include weighted averaging.

Operation 414 adjusting the merged profile 411 using adjustment fields 415, as shown in graph 416. The adjustment fields 415 can be calculated and applied using a model, such as a model that includes one or more machine learning and/or artificial intelligence algorithms. The model can use other measurements, such as film thickness measurements conducted on processed substrates and/or substrates being processed to determine film uniformities and/or film deposition rates.

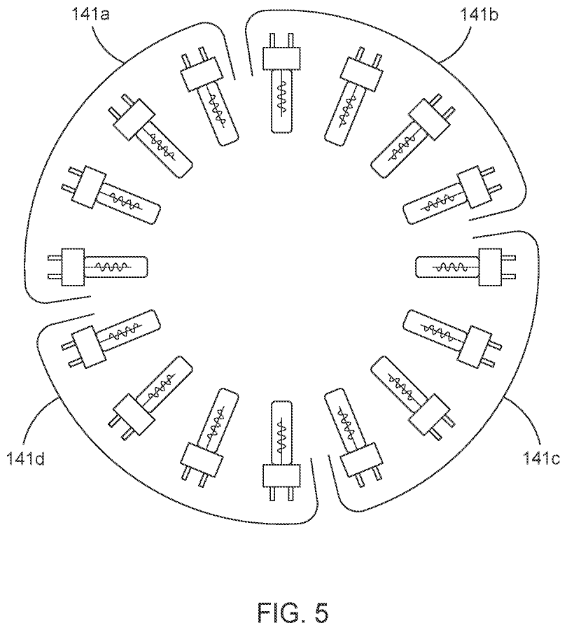

FIG. 5 is a schematic top view of the upper heat sources 141 shown in FIG. 1, according to one or more embodiments.

The upper heat sources 141 can be grouped into a plurality of one or more sets 141a-141d (four exemplary sets of four heat sources each are shown in FIG. 5). Each set 141a-141d is configured to heat a respective region of the substrate 102. As described above, one or more of the sets 141a-141d are correlated to at least one portion of a signal profile that is outside of the range, and heating power is adjusted for the correlated one or more of the sets 141a-141d. The lower heat sources 143 can be arranged, correlated, and/or adjusted in a similar manner.

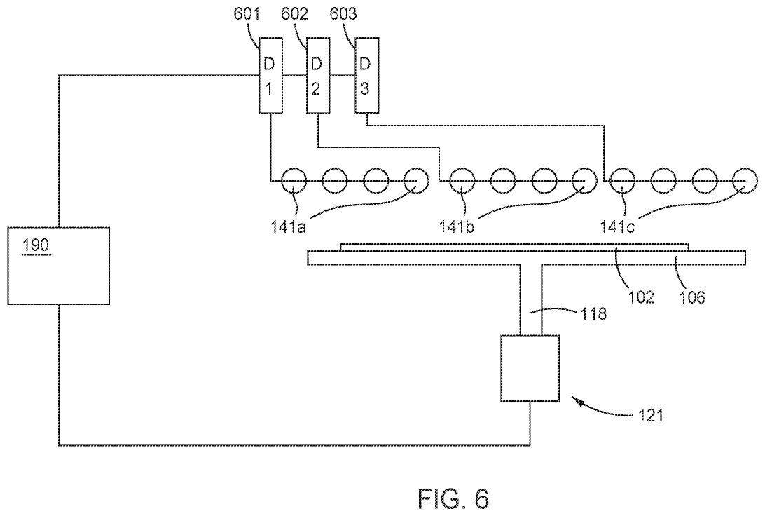

FIG. 6 is a schematic side view of the upper heat sources 141 shown in FIG. 5, according to one or more embodiments.

Each set 141a-141d of heat sources receives a heating power from a respective power supply 601, 602, 603 of a plurality of power supplies that are controlled by the controller 190.

FIG. 7 is a schematic top view of the processing chamber 100 during operations 302, 304, and 306 of the method 300 shown in FIG. 3, according to one or more embodiments.

The substrate support 106 is rotated such that a field of view 702 of sensor 197 is scanned across one or more sections 704 of the substrate 102, and/or the substrate support 106. The field of view 702 is substantially stationary during the scanning such that the one or more sections 704 extend arcuately (e.g., azimuthally, such as circumferentially). The substrate support 106 can make one or more complete revolutions such that the one or more sections 704 can make a complete ring, for example.

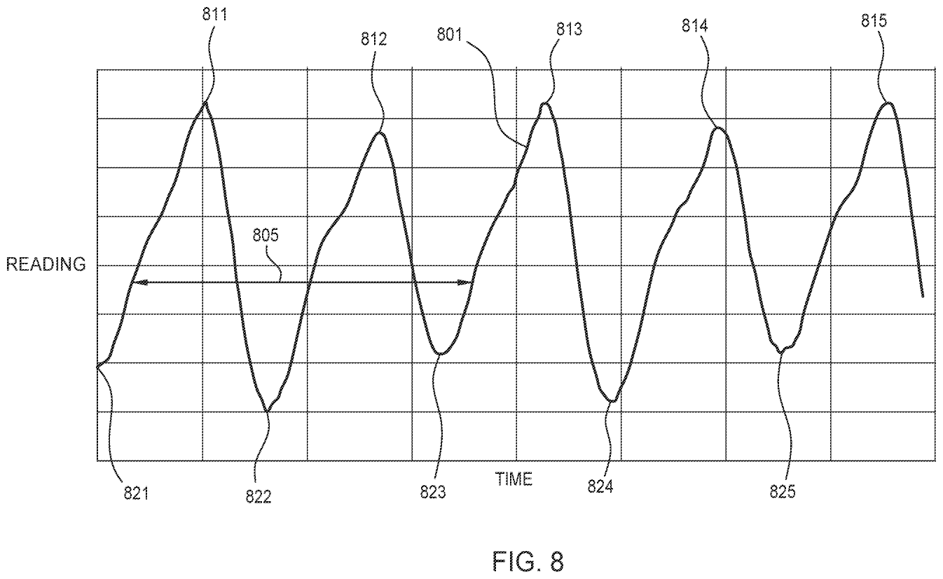

FIG. 8 is a schematic graphical view of an exemplary signal profile 801 created using the implementation shown in FIG. 7, according to one or more embodiments.

The signal profile 801 (e.g., a temperature profile) includes one or more peaks 811-815 and one or more troughs 821-825. As discussed above, analyzing the signal profile 801 can include identifying a highest peak 811 and a lowest trough 822. In one or more embodiments, the highest peak 811 indicates a largest warpage (e.g., bow) of a substrate and/or the lowest trough 822 indicates a contact point of the substrate with the substrate support. In one or more embodiments, the highest peak 811 can indicate a contact point of the substrate with the substrate support and/or the lowest trough 822 can indicate a largest warpage (e.g., bow) of the substrate.

As an example, one or more of the sets 141a-141d shown in FIG. 5 are correlated to the troughs 821-825, and heating power is adjusted for the one or more of the sets 141a-141d that are correlated to the troughs 821-825.

Analyzing the signal profile 801 can include taking a standard deviation of the signal profile 801 (e.g., by taking a standard deviation under the signal profile 801). Arrow 805 indicates one complete revolution of the substrate support 106.

FIG. 9 is a schematic top view of the processing chamber 100 during operations 302, 304, and 306 of the method 300 shown in FIG. 3, according to one or more embodiments.

The substrate support 106 is rotated such that a field of view 902 of sensor 197 is scanned across one or more sections 904 of the substrate 102, and/or the substrate support 106. The field of view 902 is moved (e.g., linearly, such as radially along direction D1 relative to a center of the substrate support 106) during the scanning such that the one or more sections 904 extend radially (e.g., in addition to azimuthally). In one or more embodiments, the field of view 902 is scanned at least partially between a center of the substrate support 106 and an outer radius 909. The substrate support 106 can make one or more complete revolutions such that the one or more sections 904 can make the shapes of lobes (as shown in FIG. 9), for example. In one or more embodiments, the field of view 902 is moved by pivoting the sensor 197 by a plurality of angular increments A1 (shown in FIG. 1). The sensor 197 can be pivoted by the angular increment A1 between collected data points. In one or more embodiments, the angular increment A1 is less than 5 degrees, such as about 1.8 degrees, between the data points. In one or more embodiments, the pivoting causes a pitch between collected data points. The pitch is less than 25 mm, such as about 10 mm.

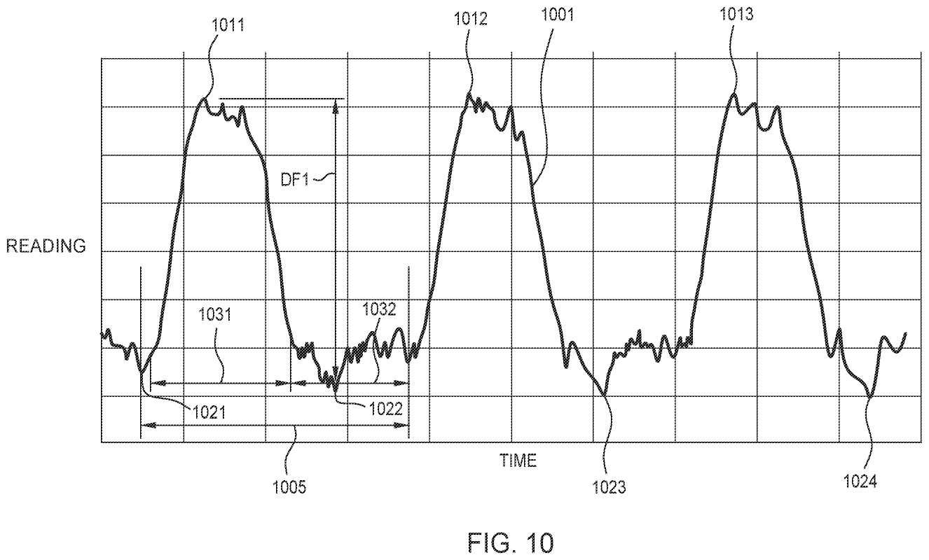

FIG. 10 is a schematic graphical view of an exemplary signal profile 1001 created using the implementation shown in FIG. 9, according to one or more embodiments. In one or more embodiments, the signal profile 1001 is a temperature profile.

The signal profile 1001 includes one or more peaks 1011-1013 and one or more troughs 1021-1024.

Arrow 1005 indicates one complete revolution of the substrate support for the signal profile 1001.

The signal profile 1001 includes a signal difference DF1 (e.g., a temperature difference). The present disclosure contemplates that the signal difference DF1 can be outside of the range.

As an exemplary implementation the set 141c of upper heat sources shown in FIG. 5 can be correlated to a first section 1031 of the signal profile 1001, and/or the set 141d of upper heat sources shown in FIG. 5 can be correlated to a second section 1032 of the signal profile 1001.

Benefits of the present disclosure include accurate adjustment of heating and/or deposition uniformity; real-time adjustment of heating and/or deposition uniformity; reduced, mitigated, or eliminated use of certain corrective measures (such as pre-heating); reduced inefficiencies; accurately and efficiently accounting for process drift (such as aging and wear of chamber components); accurately and efficiently accounting for substrate warpage (e.g., bowing); adjustability of parameters (such as temperatures, deposition uniformities, and/or deposition rates (e.g., in nm per minute)) across a variety of operation conditions (such as low rotation speeds, high pressures, and/or low flow rates); broader and/or more modular ranges of adjustability; and increased deposition uniformity and/or deposition rates. Benefits of the present disclosure also include reduced waste of substrates.

Benefits of the present disclosure further include increased component lifespan; reduced chamber downtime; reduced processing delays; and increased throughput. Benefits of the present disclosure also include enhanced deposition repeatability and/or cleaning repeatability.

It is contemplated that one or more aspects disclosed herein may be combined. As an example, one or more aspects, features, components, operations and/or properties of the processing chamber 100, the controller 190, the one or more sensors 195, 196, 197, 198, the method 300, the exemplary implementation shown in FIG. 4, the sets 141a-141d of heat sources, the power supplies 601-603, the exemplary implementation shown in FIG. 7, the signal profile 801, the exemplary implementation shown in FIG. 9, and/or the signal profile 1001, may be combined. For example, the operations and/or parameters described in relation to FIGS. 4, 7, and/or 9 can be combined with the operations and/or the parameters of the method 300. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A method of adjusting uniformity for substrate processing applicable for semiconductor manufacturing, the method comprising:
heating an internal volume of a processing chamber using a target value;
scanning a sensor across one or more sections to take a plurality of readings;
generating a signal profile including the plurality of readings;
analyzing the signal profile by comparing the signal profile to a range; and
adjusting one or more heating parameters if at least one portion of the signal profile is outside of the range, the adjusting comprising:
identifying a set of one or more heat sources that correlate with the at least one portion of the signal profile; and
adjusting a heating power by an adjustment factor for the set of one or more heat sources.

2. The method of claim 1, wherein the analyzing comprises:
identifying a signal difference in the signal profile; and
determining if the signal difference is within or outside of the range.

3. The method of claim 2, wherein the identifying of the signal difference comprises identifying one or more peaks and one or more troughs of the signal profile, and the set of one or more heat sources is correlated with at least one of the one or more troughs.

4. The method of claim 2, wherein the adjustment factor is a ratio equal to a threshold ratio of the target signal added to a value of 1.0.

5. The method of claim 4, wherein a field of view of the sensor is substantially stationary during the scanning such that the one or more sections extend azimuthally, the range is less than the threshold ratio, and the threshold ratio is 0.025.

6. The method of claim 4, wherein a field of view of the sensor is moved during the scanning such that the one or more sections extend radially, and the range is less than the threshold ratio, and the threshold ratio is 0.10.

7. The method of claim 2, wherein the identifying of the signal difference comprises determining a standard deviation of the signal profile.

8. The method of claim 1, further comprising:
rotating a substrate support, wherein the scanning is conducted while the substrate support is rotated.

9. The method of claim 8, wherein:
the one or more sections are disposed along the substrate support or along a substrate positioned on the substrate support; and
the target value is a target temperature, the sensor is a temperature sensor, the plurality of readings are a plurality of temperature readings, and the signal profile is a temperature profile.

10. A non-transitory computer readable medium applicable for semiconductor manufacturing, the non-transitory computer readable medium comprising instructions that when executed cause a plurality of operations to be conducted, the plurality of operations comprising:
analyzing a signal profile by comparing the signal profile to a range, the range is less than a threshold ratio of a target value, the threshold ratio is 0.10, and the analyzing comprising:
identifying a signal difference in the signal profile, and
determining if the signal difference is within or outside of the range; and
adjusting one or more heating parameters if at least one portion of the signal profile is outside of the range, the adjusting comprising:
identifying a set of one or more heat sources that correlate with the at least one portion of the signal profile, and
adjusting a heating power by an adjustment factor for the set of one or more heat sources.

11. The non-transitory computer readable medium of claim 10, wherein the plurality of operations further comprise:
prior to the analyzing of the signal profile, generating the signal profile, the signal profile comprising a plurality of readings.

12. The non-transitory computer readable medium of claim 10, wherein the identifying of the signal difference comprises identifying one or more peaks and one or more troughs of the signal profile, and the set of one or more heat sources is correlated with at least one of the one or more troughs.

13. The non-transitory computer readable medium of claim 12, wherein the signal difference is a difference between one of the one or more peaks and an adjacent trough of the one or more troughs.

14. The non-transitory computer readable medium of claim 13, wherein the adjacent trough is within one revolution of the one of the one or more peaks.

15. The non-transitory computer readable medium of claim 12, wherein the signal difference is a difference between a highest peak of the one or more peaks and a lowest trough of the one or more troughs.

16. The non-transitory computer readable medium of claim 10, wherein the threshold ratio is 0.025.

17. The non-transitory computer readable medium of claim 10, wherein the identifying of the signal difference comprises determining a standard deviation of the signal profile.

18. The non-transitory computer readable medium of claim 10, wherein the adjustment factor is a ratio equal to a threshold ratio of the target value added to a value of 1.0.

19. A system for processing substrates and applicable for semiconductor manufacturing, the system comprising:
a chamber body comprising one or more sidewalls;
a window, the one or more sidewalls and the window at least partially defining an internal volume;
one or more heat sources configured to heat the internal volume;
a substrate support disposed in the internal volume;
a sensor configured to sense parameters in the internal volume; and
a controller comprising instructions that, when executed, cause a plurality of operations to be conducted, the plurality of operations comprising:
generating a signal profile, the signal profile comprising a plurality of readings,
analyzing the signal profile by comparing the signal profile to a range, the range is less than a threshold ratio of a target value, the threshold ratio is 0.10, and the analyzing comprising:
identifying a signal difference in the signal profile, and
determining if the signal difference is within or outside of the range,
and
adjusting one or more heating parameters if at least one portion of the signal profile is outside of the range, the adjusting comprising:
identifying a set of one or more heat sources that correlate with the at least one portion of the signal profile, and
adjusting a heating power by an adjustment factor for the set of one or more heat sources.

20. The system of claim 19, wherein the identifying of the signal difference comprises determining a standard deviation of the signal profile.
